(19) United States
(12) Patent Application Publication
(10) Pub. No.: US 2026/0191120 A1
(43) Pub. Date: Jul. 2, 2026

(54) SEMICONDUCTOR PACKAGE WITH STACKED SEMICONDUCTOR DIES

(71) Applicant: Samsung Electronics Co., Ltd., Suwon-si (KR)

(72) Inventors: MINWOO LEE, Suwon-si (KR); JOONHO JUN, Suwon-si (KR); DUK SUNG KIM, Suwon-si (KR)

(21) Appl. No.: 19/432,828

(22) Filed: Dec. 24, 2025

(30) Foreign Application Priority Data
Dec. 30, 2024 (KR) 10-2024-0201211
Jan. 16, 2025 (KR) 10-2025-0006941

(51) Int. Cl. H10W 90/00; H10B 80/00; H10D 80/30; H10W 20/20; H10W 90/20

(52) U.S. Cl. CPC H10W 90/792; H10B 80/00; H10D 80/30; H10W 20/211; H10W 90/297

(57) ABSTRACT

A semiconductor package includes a plurality of stacked memory core dies connected to first data lines, a logic die including a processor connected to second data lines, and a buffer die stacked between the plurality of memory core dies and the logic die and including a data line reconfiguration circuit connected to the first data lines and the second data lines. The data line reconfiguration circuit includes at least one of a multiplexer circuit, a serializer/deserializer circuit, or a compressor.

### CROSS-REFERENCE TO RELATED APPLICATIONS

The application claims benefit of priority under 35 U.S.C. § 119 to Korean Patent Application Nos. 10-2024-0201211 filed on Dec. 30, 2024, and 10-2025-0006941 filed on Jan. 16, 2025, in the Korean Intellectual Property Office, the contents of which are incorporated by reference herein in their entirety.

### BACKGROUND

The present disclosure relates generally to a semiconductor package.

As electronic products are miniaturized, large-capacity, high-performance, high-integration and high-speed semiconductor packages can be used. Semiconductor packages including stacked semiconductor chips are being developed. Technologies such as AI computing rely on computational chips with fast processing speeds and high-bandwidth memories. Therefore, the demand for high-bandwidth memories is rapidly increasing.

### SUMMARY

One or more example implementations provide a semiconductor package with improved integration.

According to some implementations, a semiconductor package comprises a plurality of stacked memory core dies connected to first data lines, a logic die including a processor connected to second data lines, and a buffer die stacked between the plurality of memory core dies and the logic die and including a data line reconfiguration circuit connected to the first data lines and the second data lines. The data line reconfiguration circuit includes a multiplexer circuit, a serializer/deserializer circuit, or a compressor.

According to some implementations, a semiconductor package comprises a logic die, and a plurality of memory core dies stacked on the logic die. The logic die includes a processor, a data line reconfiguration circuit, first data lines connected to the plurality of memory core dies and the data line reconfiguration circuit, and second data lines connected to the processor and the data line reconfiguration circuit. The data line reconfiguration circuit includes a multiplexer circuit, a serializer/deserializer circuit, or a compressor.

According to some implementations, a semiconductor package comprises a package substrate, a logic die stacked on the package substrate and including a processor, a buffer die stacked on the logic die, and a memory core die stacked on the buffer die. The buffer die includes a data line reconfiguration circuit, a plurality of first bonding pads configured to electrically connect the data line reconfiguration circuit and the memory core die, and a plurality of second connection bonding pads configured to electrically connect the data line reconfiguration circuit and the processor. A number of the plurality of first bonding pads is greater than a number of the plurality of second connection bonding pads. The data line reconfiguration circuit includes a multiplexer circuit, a serializer/deserializer circuit, or a compressor.

Additional aspects will be set forth in part in the description which follows and, in part, will be apparent from the description, or may be learned by practice of the presented implementations.

### BRIEF DESCRIPTION OF DRAWINGS

The above and other aspects, features, and advantages of certain implementations of the present disclosure will be more apparent from the following description taken in conjunction with the accompanying drawings, in which:

FIG. 1 is a cross-sectional view of a semiconductor package according to exemplary implementations.

FIG. 2 is a flowchart of a manufacturing method of a semiconductor package according to exemplary implementations.

FIGS. 3, 4, 5, 6, 7, 8 and 9 are diagrams for explaining the manufacturing method of the semiconductor package of FIG. 2.

FIG. 10 is a cross-sectional view of a semiconductor package according to exemplary implementations.

FIG. 11 is a cross-sectional view of a semiconductor package according to exemplary implementations.

FIG. 12 is a cross-sectional view of a semiconductor package according to exemplary implementations.

### DETAILED DESCRIPTION

Hereinafter, example implementations are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, or as “contacting” or “in contact with” another element (or using any form of the word “contact”), there are no intervening elements or layers present.

Implementations described herein are example implementations, and thus, the present disclosure is not limited thereto, and may be realized in various other forms. Each example implementation provided in the following description is not excluded from being associated with one or more features of another example or another example implementation also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

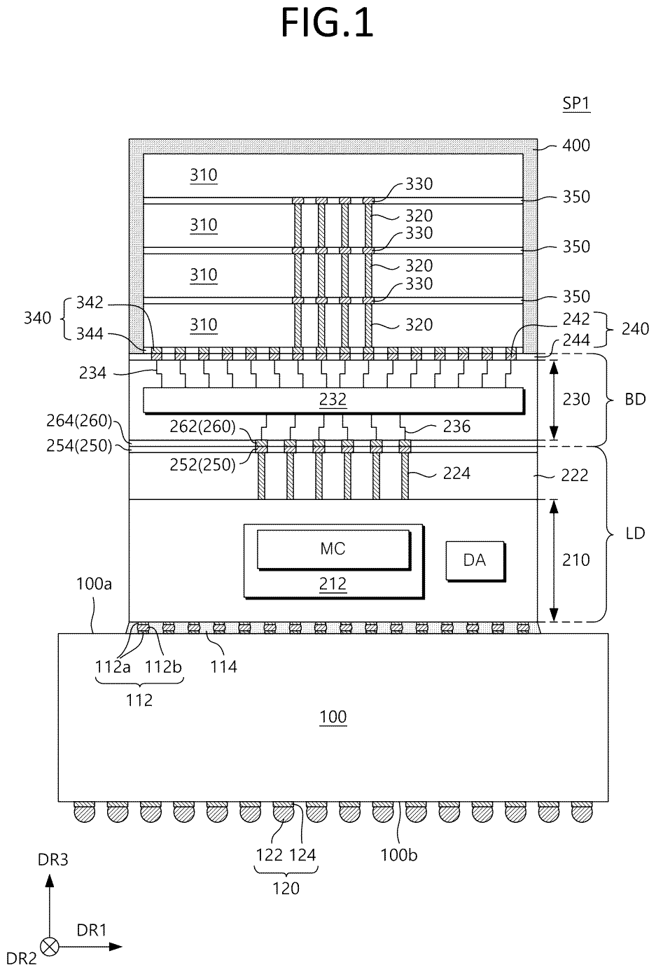

FIG. 1 is a cross-sectional view of a semiconductor package according to exemplary implementations.

Referring to FIG. 1, a semiconductor package SP1 may be provided. The semiconductor package SP1 may include a package substrate 100, a logic die LD, a buffer die BD, and memory core dies 310. The package substrate 100 may be provided at an lower portion of the semiconductor package SP1. The package substrate 100 may include a first surface 100a and a second surface 100b facing opposite directions. In exemplary implementations, the first surface 100a and the second surface 100b may extend along a first direction DR1 and a second direction DR2 that crossing each other. The first surface 100a may be spaced apart from the second surface 100b along a third direction DR3. For example, the first direction DR1, the second direction DR2, and the third direction DR3 may be perpendicular to each other.

The logic die LD, the buffer die BD, and a plurality of memory core dies 310 may be provided in sequence along the third direction DR3 on the first surface 100a of the package substrate 100. The package substrate 100 may be configured to provide signals supplied from the logic die LD, the buffer die BD, and the plurality of memory core dies 310 to a device outside the semiconductor package SP1. The package substrate 100 may be configured to provide power and signals supplied from a device outside the semiconductor package SP1 to the logic die LD and the plurality of memory core dies 310. For example, the signals may include control signals and data signals. The package substrate 100 may be configured to support the logic die LD, the buffer die BD, and the plurality of memory core dies 310. For example, the package substrate 100 may include a printed circuit board or a ceramic substrate. The package substrate 100 may include at least one layer of wiring. For example, the wiring of the package substrate 100 may be formed in multiple layers. The multi-layer wiring may be connected to each other through vias.

The logic die LD may include a logic layer 210 and a silicon substrate layer 222. In exemplary implementations, the logic die LD may be referred to as a semiconductor device. The logic layer 210 may include a processor 212 and a direct access interface DA. In exemplary implementations, the processor 212 may be configured to control the memory core dies. For example, the processor 212 may be any one of a GPU (Graphic Processing Unit), CPU (Central Processing Unit), FPGA (Field Programmable Gate Array), and ASIC (Application-Specific Integrated Circuit). The processor 212 may include a memory controller MC. The memory controller MC may be electrically connected to the memory core dies 310 and configured to transmit signals to the memory core dies 310 or receive signals provided from the memory core dies 310. For example, signals provided from the memory controller MC to the memory core dies 310 may include address signals for selecting a memory location, command signals for transmitting read or write instructions, and data signals for transmitting data. For example, signals provided from the memory core dies 310 to the memory controller MC may include data signals for transmitting data.

The direct access interface DA may be configured to test the memory core dies 310. When the memory core dies 310 include DRAM, for example, the direct access interface DA may be configured to test DRAM random access performance, latency, bandwidth, and cell reliability.

The logic layer 210 may have a structure as needed. In exemplary implementations, the logic layer 210 may include a semiconductor layer with circuits formed to implement the processor 212 and the direct access interface DA, an insulation layer formed on the semiconductor layer, and horizontal wirings and vias within the insulation layer. For example, the semiconductor layer may be a silicon layer.

The silicon substrate layer 222 may be provided between the logic layer 210 and the buffer die BD. Connection through vias 224 may be provided within the silicon substrate layer 222. The connection through vias 224 may penetrate or extend through the silicon substrate layer 222. For example, the connection through vias 224 may extend along the third direction DR3 from the bottom surface of the silicon substrate 222 to the interior of the logic layer 210. In exemplary implementations, the connection through vias 224 may be configured to transmit and receive signals provided from the processor 212 and signals provided to the processor 212. For example, horizontal wirings and vias may be provided between the connection through vias 224 and the processor 212 to electrically connect the connection through vias 224 and the processor 212. The connection through vias 224 may include an electrically conductive material. For example, the connection through vias 224 may include tungsten, aluminum, copper, alloys thereof, or combinations thereof. The connection through vias 224 may be insulated from the silicon substrate layer 222 due to an insulation layer surrounding the connection through vias 224. For example, the insulation layer may include silicon oxide, silicon nitride, or silicon oxynitride. Meanwhile, the locations of the connection through vias 224 seen on the first direction DR1 and the second direction DR2 in the logic die LD may be formed at the center or periphery of the logic die LD.

The logic die LD may further include a first connection pad layer 250 provided on the silicon substrate layer 222. The first connection pad layer 250 may include first connection bonding pads 252 and a first connection bonding insulation layer 254 surrounding the first connection bonding pads 252 on an upper part of the logic die LD. In exemplary implementations, the first connection bonding pads 252 may be configured to be electrically connected to the connection through vias 224, respectively. For example, the first connection bonding pads 252 may directly contact the connection through vias 224, respectively. The first connection bonding pads 252 may include a metal to which metal-metal hybrid bonding can be applied. For example, the first connection bonding pads 252 may include copper (Cu). The first connection bonding insulation layer 254 may include an insulating material to which nonmetal-nonmetal hybrid bonding can be applied. For example, the first connection bonding insulation layer 254 may include silicon oxide, silicon nitride, or silicon oxynitride.

The buffer die BD may be provided on the logic die LD. The buffer die BD may include a buffer layer 230. The buffer layer 230 may include a data line reconfiguration circuit 232, first data lines 234, and second data lines 236. In exemplary implementations, the data line reconfiguration circuit 232 may reduce the number of data lines for transmitting data signals provided from the memory core dies 310 to the processor 212. For example, the data line reconfiguration circuit 232 may include a multiplexer (MUX) circuit or a serializer/deserializer (SerDes) circuit, or a compressor. The multiplexer circuit may be configured to select and combine parallel data output from memory banks of the memory core dies 310. The multiplexer circuit may be configured to transmit the combined parallel data to the processor 212. In exemplary implementations, when the data line reconfiguration circuit 232 includes a multiplexer circuit, the buffer layer 230 may further include a buffer circuit provided on the first data lines 234 between the memory core dies 310 and the data line reconfiguration circuit 232. The serializer/deserializer circuit may be configured to convert parallel data output from memory banks of the memory core dies 310 into serial signals. The serializer/deserializer circuit may be configured to transmit the serial signals to the processor 212. The compressor may be configured to compress parallel data output from memory banks of the memory core dies 310. The compressor may be configured to transmit the compressed parallel data to the processor 212. Accordingly, the number of second data lines 236 between the processor 212 and the data line reconfiguration circuit 232 may be less than the number of first data lines 234 between the memory core dies 310 and the data line reconfiguration circuit 232. In exemplary implementations, the first data lines 234 and the second data lines 236 may be configured with horizontal wirings and vias.

The buffer die BD may further include a second connection pad layer 260 provided between the buffer layer 230 and the first connection pad layer 250. The second connection pad layer 260 may include second connection bonding pads 262 and a second connection bonding insulation layer 264 surrounding the second connection bonding pads 262 at a lower part of the buffer die BD. In exemplary implementations, the second connection bonding pads 262 may be configured to be electrically connected to the second data lines 236, respectively. For example, the second connection bonding pads 262 may directly contact the second data lines 236, respectively. The second connection bonding pads 262 may include a metal to which metal-metal hybrid bonding can be applied. For example, the second connection bonding pads 262 may include copper (Cu). The second connection bonding insulation layer 264 may include an insulating material to which nonmetal-nonmetal hybrid bonding can be applied. For example, the second connection bonding insulation layer 264 may include silicon oxide, silicon nitride, or silicon oxynitride.

The first connection bonding pads 252 and the second connection bonding pads 262 may be electrically connected to each other, respectively. The first connection bonding pads 252 and the second connection bonding pads 262 may directly contact each other, respectively. In exemplary implementations, the first connection bonding pads 252 and the second connection bonding pads 262 may be metal-metal hybrid bonded. In exemplary implementations, the first connection bonding pads 252 and the second connection bonding pads 262 may be connected without an interface between the first connection bonding pads 252 and the second connection bonding pads 262. In exemplary implementations, an interface may be provided between the first connection bonding pads 252 and the second connection bonding pads 262.

The first connection bonding insulation layer 254 and the second connection bonding insulation layer 264 may directly contact each other. In exemplary implementations, the first connection bonding insulation layer 254 and the second connection bonding insulation layer 264 may be nonmetal-nonmetal hybrid bonded. For example, the first connection bonding insulation layer 254 and the second connection bonding insulation layer 264 may be covalently bonded. In exemplary implementations, the first connection bonding insulation layer 254 and the second connection bonding insulation layer 264 may be connected without an interface between the first connection bonding insulation layer 254 and the second connection bonding insulation layer 264. In exemplary implementations, an interface may be provided between the first connection bonding insulation layer 254 and the second connection bonding insulation layer 264.

The buffer die BD may further include a first pad layer 240 provided on the buffer layer 230. The first pad layer 240 may include first bonding pads 242 and a first bonding insulation layer 244 surrounding the first bonding pads 242 on an upper part of the buffer die BD. In exemplary implementations, the first bonding pads 242 may be configured to be electrically connected to the first data lines 234, respectively. For example, the first bonding pads 242 may directly contact the first data lines 234, respectively. The first bonding pads 242 may include a metal to which metal-metal hybrid bonding can be applied. For example, the first bonding pads 242 may include copper (Cu). The first bonding insulation layer 244 may include an insulating material to which nonmetal-nonmetal hybrid bonding can be applied. For example, the first bonding insulation layer 244 may include silicon oxide, silicon nitride, or silicon oxynitride. The number of the first bonding pads 242 may be greater than the number of the first connection bonding pads 252 and the number of the second connection bonding pads 262. The number of the first bonding pads 242 may be greater than the number of the connection through vias 224.

The memory core dies 310 may be provided on the buffer die BD. Four memory core dies 310 are shown as an example. In exemplary implementations, the number of memory core dies 310 may be determined as needed. Each of the memory core dies 310 may include memory devices. For example, each of the memory core dies 310 may include volatile memory (e.g., DRAM (Dynamic Random Access Memory), SRAM (Static Random Access Memory)) or non-volatile memory (e.g., PRAM (Phase-change Random Access Memory), MRAM (Magnetoresistive Random Access Memory), FeRAM (Ferroelectric Random Access Memory), RRAM (Resistive Random Access Memory)).

Memory through vias 320 penetrating from or extending through the lowermost memory core die 310 to the memory core die 310 located just below the topmost memory core die 310 may be provided. The memory through vias 320 may include an electrically conductive material. For example, the memory through vias 320 may include tungsten, aluminum, copper, alloys thereof, or combinations thereof. The memory through vias 320 may be configured to transmit signals provided from the memory core dies 310 to the outside of the memory core dies 310, or to transmit signals provided from the outside of the memory core dies 310 to the memory core dies 310.

An upper pad structure 330 may be provided between a pair of memory through vias 320 facing each other along the third direction DR3. In exemplary implementations, the upper pad structure 330 may be formed by metal-metal hybrid bonding a pair of pads. For example, the upper pad structure 330 may include copper (Cu). An upper pad structure 330 without an interface between the pair of pads is shown as an example. In exemplary implementations, the upper pad structure 330 may include an interface between the pair of pads. A pair of memory through vias 320 spaced apart from each other along the third direction DR3 with the upper pad structure 330 between them may be electrically connected to each other by the upper pad structure 330.

Upper insulation films 350 surrounding the upper pad structures 330 may be provided between the memory core dies 310. In exemplary implementations, the upper insulation film 350 may be formed by nonmetal-nonmetal hybrid bonding a pair of insulation layers. For example, the upper insulation film 350 may include silicon oxide, silicon nitride, silicon oxynitride, or silicon oxide. For example, the pair of insulation layers may be covalently bonded. An upper insulation film 350 without an interface between the pair of insulation layers is shown as an example. In exemplary implementations, the upper insulation film 350 may include an interface provided between the pair of insulation layers. In exemplary implementations, the memory through vias 320, the upper pad structures 330, and the upper insulation films 350 may be included in adjacent memory core dies 310.

The lowermost memory core die 310 immediately adjacent to the buffer die BD may include a second pad layer 340 provided on the first pad layer 240. The second pad layer 340 may include second bonding pads 342 and a second bonding insulation layer 344 surrounding the second bonding pads 342. In exemplary implementations, the second bonding pads 342 may be configured to be electrically connected to the memory through vias 320 of the lowermost memory core die 310, respectively. Each of the memory core dies 310 may be a memory core die having a wide I/O (Wide IO). Each of the memory core dies 310 may have 512-bit, 1024-bit, or 2048-bit or more data input/output lines. The data input/output lines may be connected to the first data lines 234 of the buffer die 230 through the second bonding pads 342. The parallel input/output data of the memory core dies 310 may be sequentially or compressively transmitted to the second data lines 236 through the data line reconfiguration circuit 232 of the buffer die 230.

The second bonding pads 342 may include a metal to which metal-metal hybrid bonding can be applied. For example, the second bonding pads 342 may include copper (Cu). The number of the second bonding pads 342 may be greater than the number of the first connection bonding pads 252 and the number of the second connection bonding pads 262. The second bonding insulation layer 344 may include an insulating material to which nonmetal-nonmetal hybrid bonding can be applied. For example, the second bonding insulation layer 344 may include silicon oxide, silicon nitride, or silicon oxynitride.

The corresponding first bonding pads 242 and second bonding pads 342 may be electrically connected to each other. The first bonding pads 242 and the second bonding pads 342 may directly contact each other, respectively. In exemplary implementations, the first bonding pads 242 and the second bonding pads 342 may be metal-metal hybrid bonded. In exemplary implementations, the first bonding pads 242 and the second bonding pads 342 may be connected without an interface between them. In exemplary implementations, an interface may be provided between the first bonding pads 242 and the second bonding pads 342.

The first bonding insulation layer 244 and the second bonding insulation layer 344 may directly contact each other. In exemplary implementations, the first bonding insulation layer 244 and the second bonding insulation layer 344 may be nonmetal-nonmetal hybrid bonded. For example, the first bonding insulation layer 244 and the second bonding insulation layer 344 may be covalently bonded. In exemplary implementations, the first bonding insulation layer 244 and the second bonding insulation layer 344 may be connected without an interface between them. In exemplary implementations, an interface may be provided between the first bonding insulation layer 244 and the second bonding insulation layer 344.

A molding film 400 may be provided on the memory core dies 310. The molding film 400 may be configured to protect the memory core dies 310. For example, the molding film 400 may cover the sides of the memory core dies 310 and the top surface of the topmost memory core die 310. The molding film 400 may include an electrically insulating material. For example, the molding film 400 may include an epoxy molding compound (EMC) or an underfill material.

Internal connection structures 112 may be provided between the package substrate 100 and the logic die LD. The internal connection structures 112 may be configured to provide electrical connection between the logic die LD and the package substrate 100. For example, each of the internal connection structures 112 may include a pair of internal connection bonding pads 112a contacting the logic die LD and the package substrate 100, respectively, and a bump 112b formed between the pair of internal connection bonding pads 112a. The internal connection bonding pads 112a and the bump 112b may include an electrically conductive material. For example, the internal connection bonding pads 112a may include at least one of gold (Au), silver (Ag), platinum (Pt), aluminum (Al), copper (Cu), palladium (Pd), nickel (Ni), cobalt (Co), chromium (Cr), and titanium (Ti). For example, the bump 112b may include at least one of tin-containing alloys (e.g., PbSn, SnAg, SnCu, SnAgCu (SAC)), gold (Au), copper (Cu), and silver (Ag). Although the pair of internal connection bonding pads 112a is connected through a bump 112b in various implementations, the connection of the pair of internal connection bonding pads 112a is not limited thereto. It may be implemented through bumpless bonding, such as copper bonding mentioned above.

A gap-fill film 114 surrounding the internal connection structures 112 may be formed between the logic die LD and the package substrate 100. The gap-fill film 114 may include an electrically insulating material. For example, the gap-fill film 114 may include a non-conductive film (NCF).

External connection structures 120 may be provided on the bottom surface of the package substrate 100. The external connection structures 120 may be configured to be electrically connected to a device outside the semiconductor package SP1. For example, the external connection structures 120 may be configured to be electrically connected to a motherboard. Each of the external connection structures 120 may include an external connection pad 124 and an external connection terminal 122. The external connection pads 124 may include an electrically conductive material. For example, the external connection pads 124 may include at least one of gold (Au), silver (Ag), platinum (Pt), aluminum (Al), copper (Cu), palladium (Pd), nickel (Ni), cobalt (Co), chromium (Cr), and titanium (Ti).

External connection terminals 122 may be provided on the external connection pads 124, respectively. The external connection terminals 122 may be electrically connected to the external connection pads 124, respectively. For example, the external connection terminals 122 may be solder balls. In exemplary implementations, the external connection terminals 122 may include a conductive bump, a conductive spacer, or a pin grid array.

This disclosure may provide a semiconductor package SP1 with improved integration by arranging the buffer die BD and the memory core dies 310 on the logic die LD. The logic die LD including the processor 212 and the memory core dies 310 of this disclosure may be configured to be electrically connected to each other without an interposer between them. Accordingly, a miniaturized semiconductor package SP1 requiring fewer manufacturing resources may be provided.

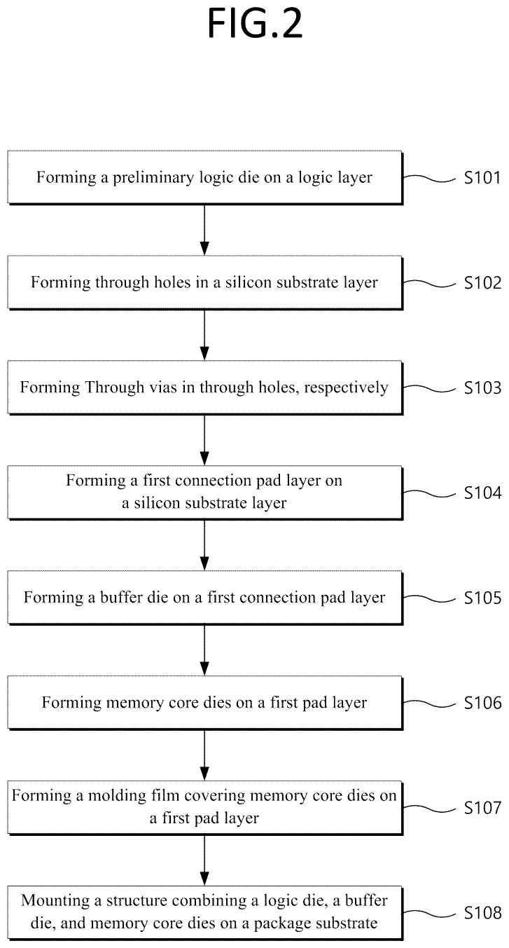

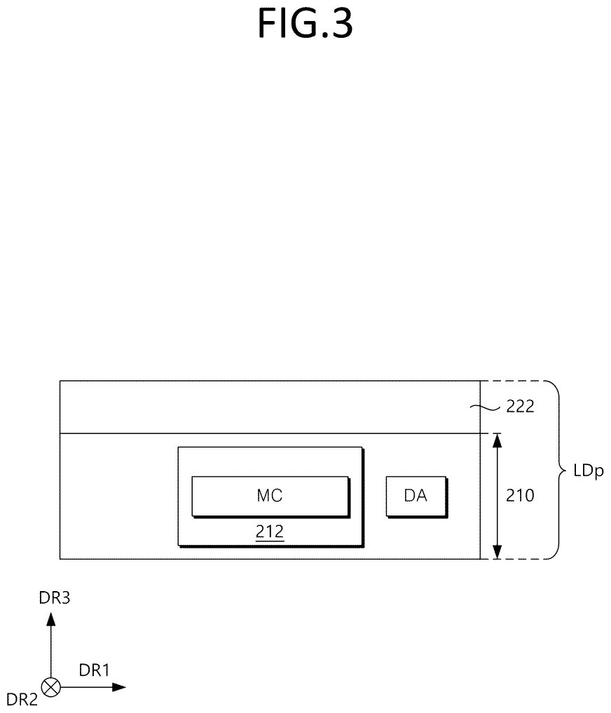

FIG. 2 is a flowchart of a manufacturing method of a semiconductor package according to exemplary implementations. FIGS. 3 to 9 are diagrams for explaining the manufacturing method of the semiconductor package of FIG. 2.

Referring to FIGS. 2 and 3, a preliminary logic die LDp may be formed on a logic layer 210 (S101). The preliminary logic die LDp may include a silicon substrate layer 222 and a logic layer 210. The logic layer 210 may include a processor 212 and a direct access interface DA. For example, the processor 212 may be any one of a GPU (Graphic Processing Unit), CPU (Central Processing Unit), FPGA (Field Programmable Gate Array), and ASIC (Application-Specific Integrated Circuit). The processor 212 may include a memory controller MC. The memory controller MC may be configured to be electrically connected to the memory core dies 310 to transmit signals to the memory core dies 310 or receive signals provided from the memory core dies 310. The logic layer 210 may have a structure as needed. In exemplary implementations, the logic layer 210 may include a semiconductor layer with circuits formed to implement the processor 212 and the direct access interface DA, an insulation layer formed on the semiconductor layer, and horizontal wirings and vias within the insulation layer. For example, the semiconductor layer may be a silicon layer.

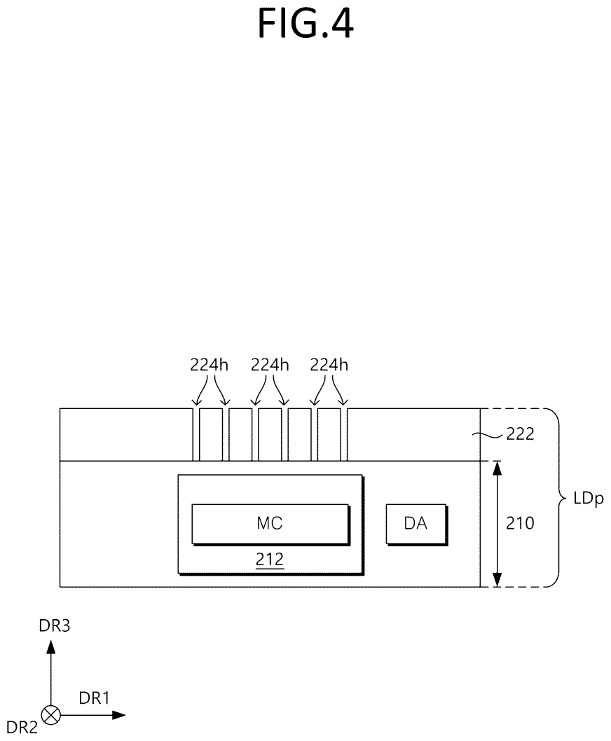

Referring to FIGS. 2 and 4, through holes 224h may be formed in the silicon substrate layer 222 (S102). The through holes 22h may be configured to extend along the third direction DR3 to penetrate or extend through the silicon substrate 222. The through holes 224h may be configured to expose required horizontal wirings and vias formed in the logic layer 210. In exemplary implementations, forming the through holes 224h may include performing an etching process using an etching mask formed on the silicon substrate layer 222. The etching mask may be removed during or after the etching process. For example, the etching process may be a dry etching process or a wet etching process.

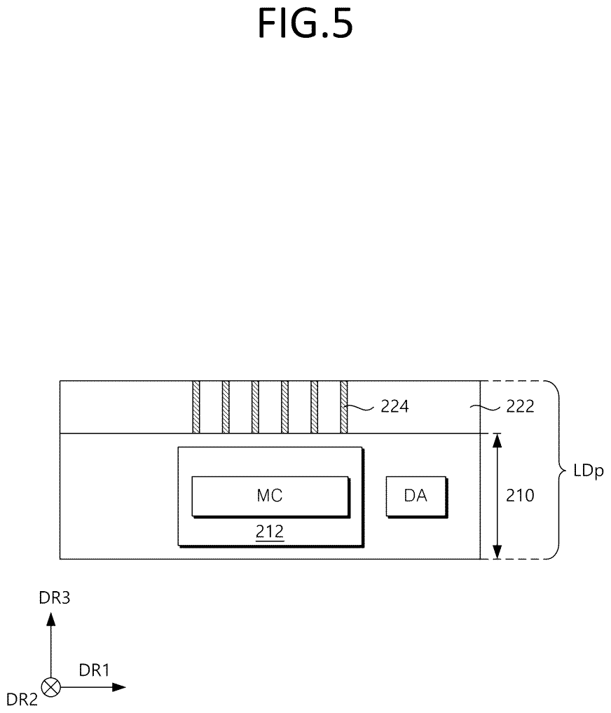

Referring to FIGS. 2 and 5, through vias 224 may be formed in the through holes 224h, respectively (S103). In exemplary implementations, before forming the through vias 224, an insulation layer may be formed on the sidewalls of the through holes 224h. For example, forming the insulation layer may include depositing an electrically insulating material on the sidewalls of the through holes 224h. The electrically insulating material may include, for example, silicon oxide, silicon nitride, or silicon oxynitride.

In exemplary implementations, forming the through vias 224 may include filling the through holes 224h, in which the insulation layer is formed, with an electrically conductive material. For example, filling with the electrically conductive material may be performed by a deposition process. The electrically conductive material may include, for example, tungsten, aluminum, copper, alloys thereof, or combinations thereof.

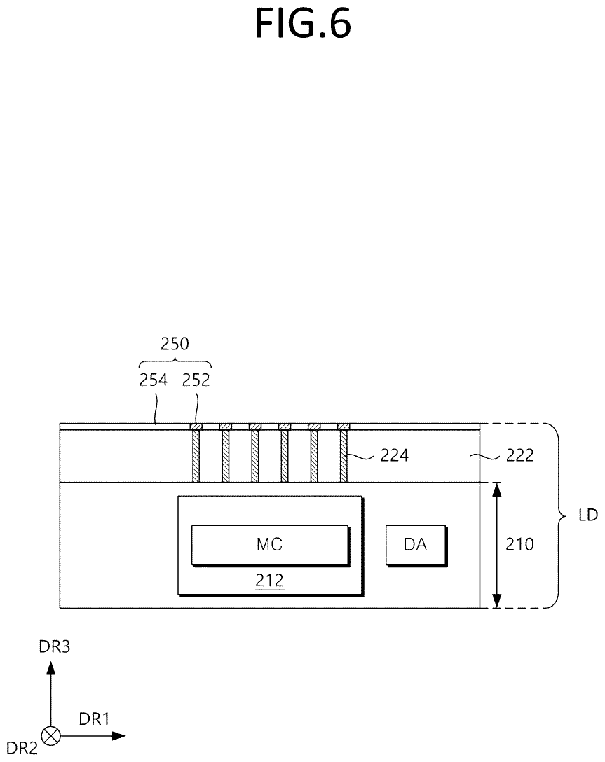

Referring to FIGS. 2 and 6, a first connection pad layer 250 may be formed on the silicon substrate layer 222 (S104). The logic layer 210, the silicon substrate layer 222, the through vias 224, and the first connection pad layer 250 may be referred to as a logic die LD. The first connection pad layer 250 may include first connection bonding pads 252 and a first connection bonding insulation layer 254. In exemplary implementations, the first connection bonding pads 252 may include a metal to which metal-metal hybrid bonding can be applied. For example, the first connection bonding pads 252 may include copper (Cu).

The first connection bonding insulation layer 254 may surround the first connection bonding pads 252. The first connection bonding insulation layer 254 may include an insulating material to which nonmetal-nonmetal hybrid bonding can be applied. For example, the first connection bonding insulation layer 254 may include silicon oxide, silicon nitride, or silicon oxynitride.

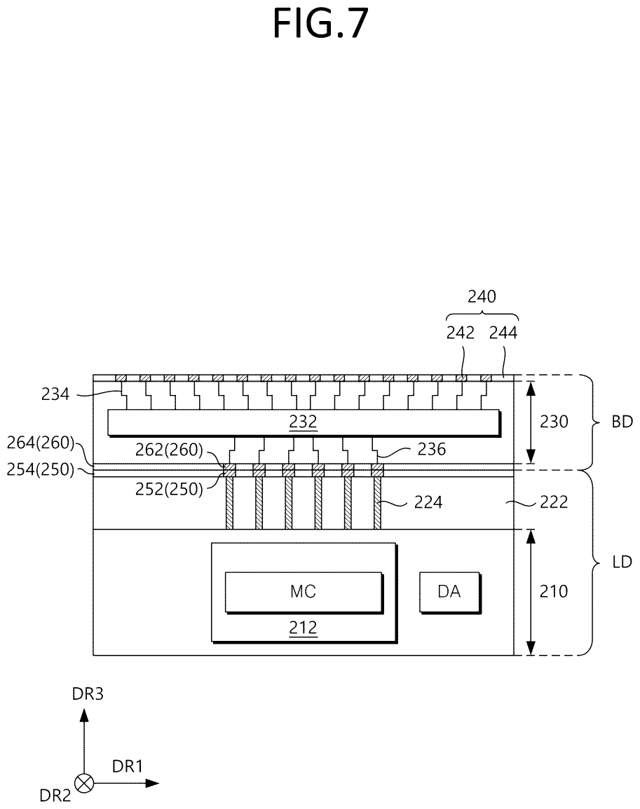

Referring to FIGS. 2 and 7, a buffer die BD may be formed on the first connection pad layer 250 (S105). For example, the buffer die BD may be bonded to the logic die LD. The buffer die BD may include a buffer layer 230, a second connection pad layer 260, and a first pad layer 240. The buffer layer 230 may include a data line reconfiguration circuit 232, first data lines 234, and second data lines 236. In exemplary implementations, the data line reconfiguration circuit 232 may reduce the number of data lines for transmitting data signals provided from the memory core dies 310 to the processor 212. For example, the data line reconfiguration circuit 232 may include a multiplexer (MUX) circuit, a serializer/deserializer (SerDes) circuit, or a compressor. The multiplexer circuit may be configured to select and combine parallel data output from memory banks of the memory core dies 310. The multiplexer circuit may be configured to transmit the combined parallel data to the processor 212. In exemplary implementations, when the data line reconfiguration circuit 232 includes a multiplexer circuit, the buffer layer 230 may further include a buffer circuit provided on the first data lines 234 between the memory core dies 310 and the data line reconfiguration circuit 232. The serializer/deserializer circuit may be configured to convert parallel data output from memory banks of the memory core dies 310 into serial signals. The serializer/deserializer circuit may be configured to transmit the serial signals to the processor 212. The compressor may be configured to compress parallel data output from memory banks of the memory core dies 310. The compressor may be configured to transmit the compressed parallel data to the processor 212. Accordingly, the number of second data lines 236 used for data transmission between the processor 212 and the data line reconfiguration circuit 232 may be less than the number of first data lines 234 between the memory core dies 310 and the data line reconfiguration circuit 232. In exemplary implementations, the first data lines 234 and the second data lines 236 may be constructed with horizontal wirings and vias and through vias.

The second connection pad layer 260 may be formed between the first connection pad layer 250 and the buffer layer 230. The second connection pad layer 260 may include second connection bonding pads 262 and a second connection bonding insulation layer 264. In exemplary implementations, the second connection bonding pads 262 may include a metal to which metal-metal hybrid bonding can be applied. For example, the second connection bonding pads 262 may include copper (Cu). The second connection bonding pads 262 may be bonded to the first connection bonding pads 252, respectively. In exemplary implementations, the first connection bonding pads 252 and the second connection bonding pads 262 may be connected without an interface between the first connection bonding pads 252 and the second connection bonding pads 262. In exemplary implementations, an interface may be provided between the first connection bonding pads 252 and the second connection bonding pads 262. The second connection bonding pads 262 may be electrically connected to the corresponding first connection bonding pads 252.

The second connection bonding insulation layer 264 may be formed to surround the second connection bonding pads 262. The second connection bonding insulation layer 264 may include an insulating material to which nonmetal-nonmetal hybrid bonding can be applied. For example, the second connection bonding insulation layer 264 may include silicon oxide, silicon nitride, or silicon oxynitride. The second connection bonding insulation layer 264 may be bonded to the first connection bonding insulation layer 254. For example, the first connection bonding insulation layer 254 and the second connection bonding insulation layer 264 may be covalently bonded. In exemplary implementations, the first connection bonding insulation layer 254 and the second connection bonding insulation layer 264 may be connected without an interface between, the first connection bonding insulation layer 254 and the second connection bonding insulation layer 264. In exemplary implementations, an interface may be provided between the first connection bonding insulation layer 254 and the second connection bonding insulation layer 264.

The first pad layer 240 may be formed on the buffer layer 230. The first pad layer 240 may include first bonding pads 242 and a first bonding insulation layer 244. In exemplary implementations, the first bonding pads 242 may include a metal to which metal-metal hybrid bonding can be applied. For example, the first bonding pads 242 may include copper (Cu). The number of the first bonding pads 242 may be greater than the number of the first connection bonding pads 252 and the number of the second connection bonding pads 262. The number of the first bonding pads 242 may be greater than the number of the connection through vias 224.

The first bonding insulation layer 244 may surround the first bonding pads 242. The first bonding insulation layer 244 may include an insulating material to which nonmetal-nonmetal hybrid bonding can be applied. For example, the first bonding insulation layer 244 may include silicon oxide, silicon nitride, or silicon oxynitride.

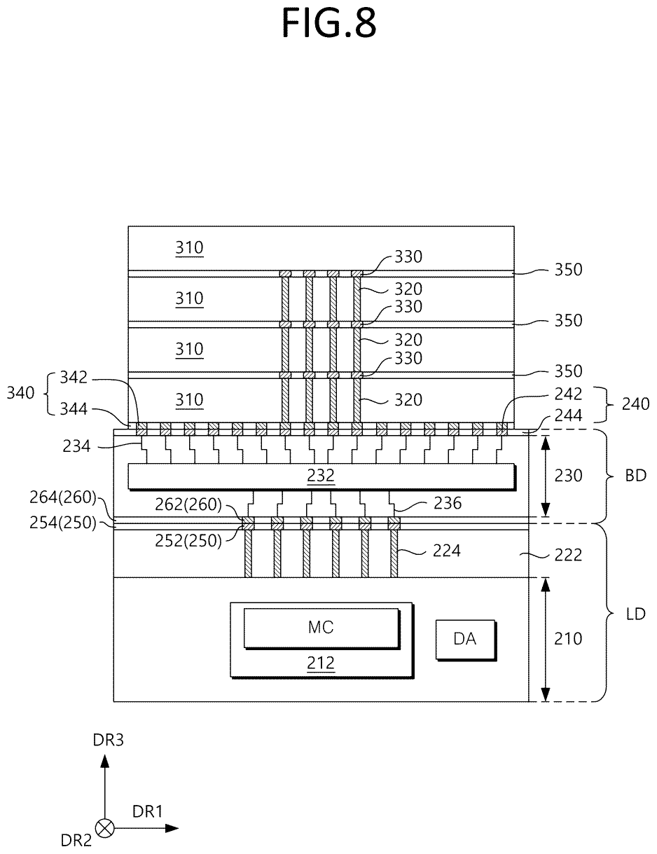

Referring to FIGS. 2 and 8, memory core dies 310 may be formed on the first pad layer 240(S106). The memory core dies 310 may be stacked along the third direction DR3. Four memory core dies 310 are shown as an example. In exemplary implementations, the number of memory core dies 310 may be determined as needed. Each of the memory core dies 310 may include memory devices. For example, each of the memory core dies 310 may include volatile memory (e.g., DRAM (Dynamic Random Access Memory), SRAM (Static Random Access Memory)) or non-volatile memory (e.g., PRAM (Phase-change Random Access Memory), MRAM (Magnetoresistive Random Access Memory), FeRAM (Ferroelectric Random Access Memory), RRAM (Resistive Random Access Memory)).

Memory through vias 320 penetrating from or extending through the lowermost memory core die 310 to the memory core die 310 located just below the topmost memory core die 310 may be formed. The memory through vias 320 may include an electrically conductive material. For example, the memory through vias 320 may include tungsten, aluminum, copper, alloys thereof, or combinations thereof.

An upper pad structure 330 may be formed between a pair of memory through vias 320 facing each other along the third direction DR3. In exemplary implementations, the upper pad structure 330 may be formed by metal-metal hybrid bonding a pair of pads. For example, the upper pad structure 330 may include copper (Cu). The upper pad structure 330 without an interface between the pair of pads is shown as an example. In exemplary implementations, the upper pad structure 330 may include an interface between the pair of pads. A pair of memory through vias 320 spaced apart from each other along the third direction DR3 with the upper pad structure 330 between the pair of memory through vias 320 may be electrically connected to each other by the upper pad structure 330.

Upper insulation films 350 surrounding the upper pad structures 330 may be formed between the memory core dies 310. In exemplary implementations, the upper insulation film 350 may be formed by nonmetal-nonmetal hybrid bonding a pair of insulation layers. For example, the upper insulation film 350 may include silicon oxide, silicon nitride, silicon oxynitride, or silicon oxide. For example, the pair of insulation layers may be covalently bonded. The upper insulation film 350 without an interface between the pair of insulation layers is shown as an example. In exemplary implementations, the upper insulation film 350 may include an interface provided between the pair of insulation layers. In exemplary implementations, the memory through vias 320, the upper pad structures 330, and the upper insulation films 350 may be included in adjacent memory core dies 310.

A second pad layer 340 may be formed between the first pad layer 240 and the lowermost memory core die 310. The second pad layer 340 may be included in the lowermost memory core die 310 immediately adjacent to the buffer die BD. The second pad layer 340 may include second bonding pads 342 and a second bonding insulation layer 344. In exemplary implementations, the second bonding pads 342 may include a metal to which metal-metal hybrid bonding can be applied. For example, the second bonding pads 342 may include copper (Cu). The second bonding pads 342 may be bonded to the first bonding pads 242, respectively. In exemplary implementations, the first bonding pads 242 and the second bonding pads 342 may be connected without an interface between the first bonding pads 242 and the second bonding pads 342. In exemplary implementations, an interface may be provided between the first bonding pads 242 and the second bonding pads 342. The second bonding pads 342 may be electrically connected to the corresponding first bonding pads 242. The number of the second bonding pads 342 may be greater than the number of the first connection bonding pads 252 and the number of the second connection bonding pads 262. The number of the second bonding pads 342 may be greater than the number of the connection through vias 224.

The second bonding insulation layer 344 may be formed to surround the second bonding pads 342. The second bonding insulation layer 344 may include an insulating material to which nonmetal-nonmetal hybrid bonding can be applied. For example, the second bonding insulation layer 344 may include silicon oxide, silicon nitride, or silicon oxynitride. The second bonding insulation layer 344 may be bonded to the first bonding insulation layer 244. For example, the first bonding insulation layer 244 and the second bonding insulation layer 344 may be covalently bonded. In exemplary implementations, the first bonding insulation layer 244 and the second bonding insulation layer 344 may be connected without an interface between the first bonding insulation layer 244 and the second bonding insulation layer 344. In exemplary implementations, an interface may be provided between the first bonding insulation layer 244 and the second bonding insulation layer 344.

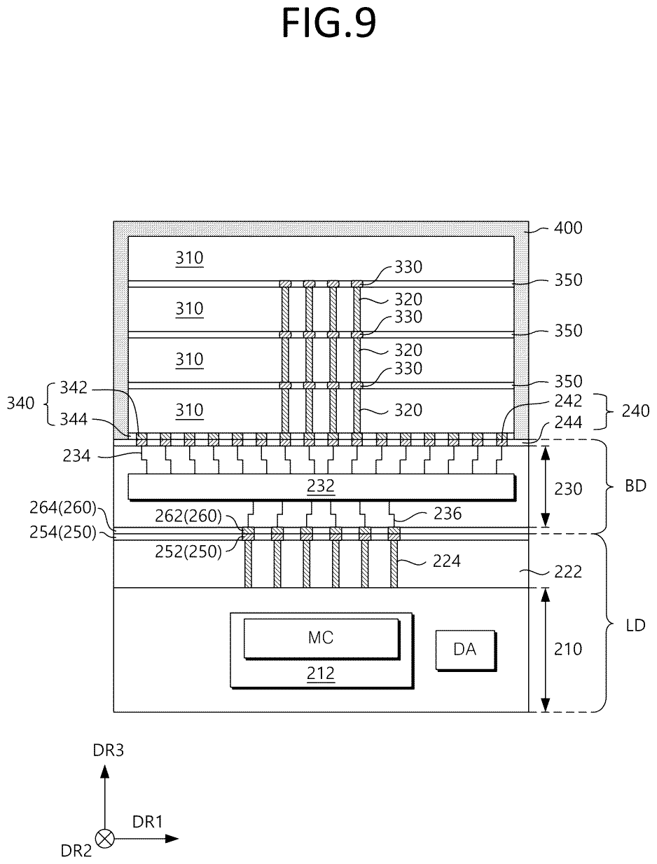

Referring to FIGS. 2 and 9, a molding film 400 covering the memory core dies 310 may be formed on the first pad layer 240 (S107). The molding film 400 may be configured to protect the memory core dies 310. For example, the molding film 400 may cover the sides of the memory core dies 310 and the top surface of the topmost memory core die 310. The molding film 400 may include an electrically insulating material. For example, the molding film 400 may include an epoxy molding compound (EMC) or an underfill material.

Referring to FIGS. 2 and 1, the structure combining the logic die LD, the buffer die BD, and the memory core dies 310 may be mounted on the package substrate 100 (S108). The bottom surface of the logic die LD may be arranged to face the first surface 100a of the package substrate 100. Internal connection structures 112 may be formed on the bottom surface of the logic die LD. The internal connection structures 112 may be configured to provide electrical connection between the logic die LD and the package substrate 100. For example, each of the internal connection structures 112 may include a pair of internal connection bonding pads 112a contacting the logic die LD and the package substrate 100, respectively, and a bump 112b formed between the pair of internal connection bonding pads 112a. The internal connection bonding pads 112a may include an electrically conductive material. For example, the internal connection bonding pads 112a may include at least one of gold (Au), silver (Ag), platinum (Pt), aluminum (Al), copper (Cu), palladium (Pd), nickel (Ni), cobalt (Co), chromium (Cr), and titanium (Ti). Although the pair of internal connection bonding pads 112a is connected through a bump 112b in various implementations, the connection of the pair of internal connection bonding pads 112a is not limited thereto. It may be implemented through bumpless bonding, such as copper bonding mentioned above.

A gap-fill film 114 surrounding the internal connection structures 112 may be formed between the logic die LD and the package substrate 100. The gap-fill film 114 may include an electrically insulating material. For example, the gap-fill film 114 may include a non-conductive film (NCF).

External connection structures 120 may be formed on the bottom surface 100b of the package substrate 100. Each of the external connection structures 120 may include an external connection pad 124 and an external connection terminal 122. The external connection pads 124 may include an electrically conductive material. For example, the external connection pads 124 may include at least one of gold (Au), silver (Ag), platinum (Pt), aluminum (Al), copper (Cu), palladium (Pd), nickel (Ni), cobalt (Co), chromium (Cr), and titanium (Ti).

External connection terminals 122 may be formed on the external connection pads 124, respectively. The external connection terminals 122 may be electrically connected to the external connection pads 124, respectively. For example, the external connection terminals 122 may be solder balls. In exemplary implementations, the external connection terminals 122 may include a conductive bump, a conductive spacer, or a pin grid array.

Accordingly, a semiconductor package SP1 with improved integration may be formed.

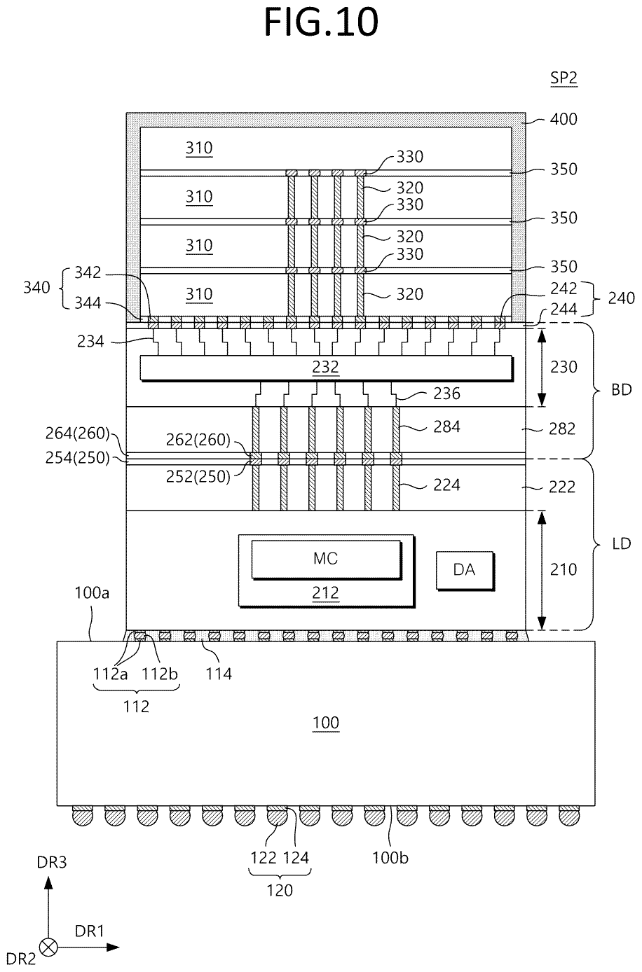

FIG. 10 is a cross-sectional view of a semiconductor package according to exemplary implementations. For conciseness, differences from what was explained with reference to FIG. 1 are primarily explained.

Referring to FIG. 10, a semiconductor package SP2 may be provided. Unlike what was explained with reference to FIG. 1, the buffer die BD may further include a buffer silicon substrate layer 282 and buffer connection through vias 284 provided between the buffer layer 230 and the second connection pad layer 260. Connection through vias 284 may be provided within the buffer silicon substrate layer 282. The connection through vias 284 may extend through the buffer silicon substrate layer 282. For example, the connection through vias 284 may extend along the third direction DR3 from the bottom surface of the buffer silicon substrate layer 282 to the interior of the buffer layer 230. The connection through vias 284 may be electrically connected to the data line reconfiguration circuit 232 by the second data lines 236. In exemplary implementations, the connection through vias 284 may be configured to transmit and receive signals provided from the data line reconfiguration circuit 232 and signals provided to the data line reconfiguration circuit 232. The connection through vias 284 may be configured to be electrically connected to the second connection bonding pads 262. In other words, the connection through vias 284 may be configured to electrically connect the second data lines 236 and the second connection bonding pads 262.

The connection through vias 284 may include an electrically conductive material. For example, the connection through vias 284 may include tungsten, aluminum, copper, alloys thereof, or combinations thereof. At this time, the connection through vias 284 may be insulated from the buffer silicon substrate layer 282 by an insulation layer surrounding the connection through vias 284. For example, the insulation layer may include silicon oxide, silicon nitride, or silicon oxynitride. From a perspective along the third direction DR3, the locations of the connection through vias 284 may be formed at the center or periphery of the buffer die BD.

This disclosure may provide a semiconductor package SP2 with improved integration.

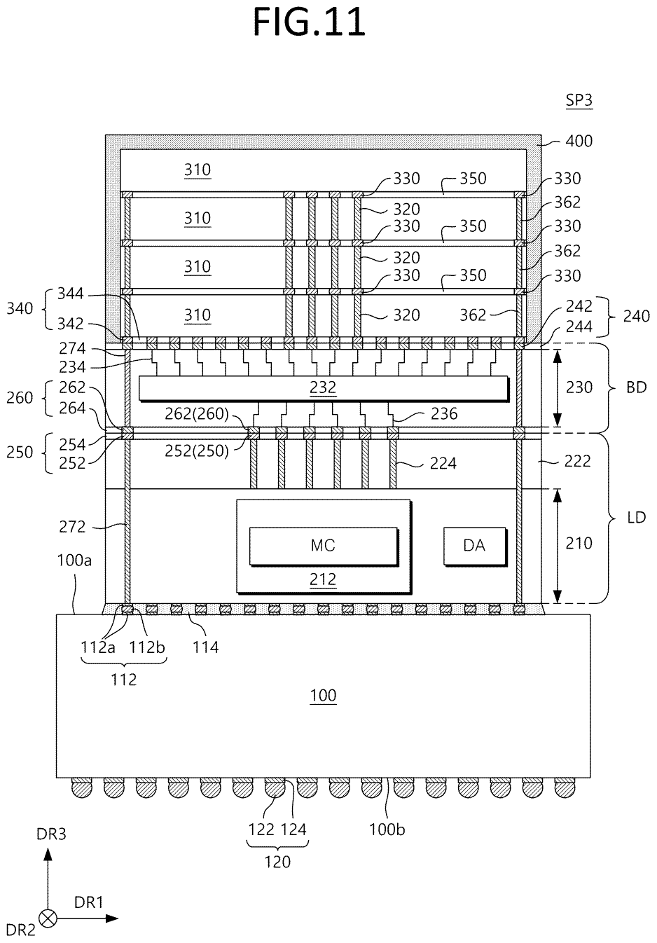

FIG. 11 is a cross-sectional view of a semiconductor package according to exemplary implementations. For conciseness, differences from what was explained with reference to FIG. 1 are primarily explained.

Referring to FIG. 11, a semiconductor package SP3 may be provided. Unlike what was explained with reference to FIG. 1, the semiconductor package SP3 may further include first lower power through vias 272, first upper power through vias 274, and second power through vias 362. The first lower power through vias 272, the first upper power through vias 274, and the second power through vias 362 may be arranged along the third direction DR3. The first lower power through vias 272 may penetrate or extend through the logic layer 210 and the silicon substrate layer 222. For example, the first lower power through vias 272 may extend along the third direction DR3. The first upper power through vias 274 may penetrate or extend through the buffer layer 230. For example, the first upper power through vias 274 may extend along the third direction DR3. The second power through vias 362 may penetrate or extend thorough the memory core dies 310. For example, the second power through vias 362 may extend along the third direction DR3.

A first lower power through via 272 and a first upper power through via 274 immediately adjacent to each other along the third direction DR3 may be electrically connected to each other by a first connection bonding pad 252 and a second connection bonding pad 262. A first upper power through via 274 and a second power through via 362 immediately adjacent to each other along the third direction DR3 may be electrically connected to each other by a first bonding pad 242 and a second bonding pad 342. Second power through vias 362 immediately adjacent to each other along the third direction DR3 may be electrically connected to each other by an upper pad structure 330. The first lower power through via 272 may be electrically connected to the package substrate 100 by an internal connection structure 112. The electrically connected second power through vias 362, upper pad structures 330, first bonding pads 242, second bonding pads 342, first lower power through vias 272, first upper power through vias 274, and internal connection structure 112 may be referred to as a power transmission line. In exemplary implementations, the power transmission line may be configured for the package substrate 100 to provide power received from a device outside the semiconductor package SP3 to at least one of the logic die LD, the buffer die BD, and the plurality of memory core dies 310.

This disclosure may provide a semiconductor package SP3 with improved integration.

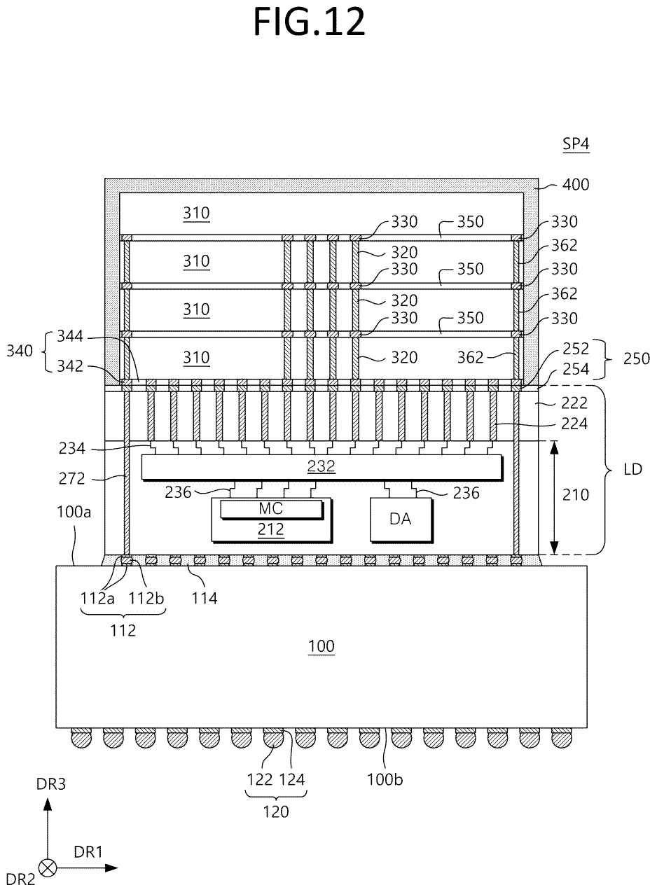

FIG. 12 is a cross-sectional view of a semiconductor package according to exemplary implementations. For conciseness, differences from what was explained with reference to FIG. 1 and FIG. 11 are primarily explained.

Referring to FIG. 12, a semiconductor package SP4 may be provided. Unlike what was explained with reference to FIG. 1, the logic die LD may be bonded to the memory core dies 310 without the buffer die (BD in FIG. 1). The first connection pad layer 250 may contact the second pad layer 340. The first connection pad layer 250 may include first connection bonding pads 252 corresponding to the second bonding pads 342. The corresponding first connection bonding pads 252 and second bonding pads 342 may be electrically connected to each other. The first connection bonding pads 252 and the second bonding pads 342 may directly contact each other, respectively. In exemplary implementations, the first connection bonding pads 252 and the second bonding pads 342 may be metal-metal hybrid bonded. In exemplary implementations, the first connection bonding pads 252 and the second bonding pads 342 may be connected without an interface between the first connection bonding pads 252 and the second bonding pads 342. In exemplary implementations, an interface may be provided between the first connection bonding pads 252 and the second bonding pads 342.

The first connection bonding insulation layer 254 and the second bonding insulation layer 344 may directly contact each other. In exemplary implementations, the first connection bonding insulation layer 254 and the second bonding insulation layer 344 may be nonmetal-nonmetal hybrid bonded. For example, the first connection bonding insulation layer 254 and the second bonding insulation layer 344 may be covalently bonded. In exemplary implementations, the first connection bonding insulation layer 254 and the second bonding insulation layer 344 may be connected without an interface between the first connection bonding insulation layer 254 and the second bonding insulation layer 344. In exemplary implementations, an interface may be provided between the first connection bonding insulation layer 254 and the second bonding insulation layer 344.

Connection through vias 224 corresponding to the first connection bonding pads 252 may be provided within the silicon substrate layer 222. The connection through vias 224 may be configured to be electrically connected to the corresponding first connection bonding pads 252.

The logic die LD may further include a data line reconfiguration circuit 232. The data line reconfiguration circuit 232 may be substantially identical to the data line reconfiguration circuit 232 explained with reference to FIG. 1.

First data lines 234 may be provided between the data line reconfiguration circuit 232 and the connection through vias 224. The first data lines 234 may be configured to electrically connect the connection through vias 224 and the data line reconfiguration circuit 232. Second data lines 236 may be provided between the data line reconfiguration circuit 232 and the processor 212 and between the data line reconfiguration circuit 232 and the direct access interface DA. For example, some of the second data lines 236 may be configured to electrically connect the data line reconfiguration circuit 232 and the processor 212, and other parts of the second data lines 236 may be configured to electrically connect the data line reconfiguration circuit 232 and the direct access interface DA.

The semiconductor package SP4 may further include first lower power through vias 272 and second power through vias 362. The first lower power through vias 272 and the second power through vias 362 may be substantially identical to the first lower power through vias 272 and the second power through vias 362 explained with reference to FIG. 11. Unlike what was explained with reference to FIG. 11, a first lower power through via 272 and a second power through via 362 immediately adjacent to each other along the third direction DR3 may be electrically connected to each other by a first connection pad 252 and a second bonding pad 342. The second power through vias 362, upper pad structures 330, second bonding pads 342, first connection bonding pads 252, first lower power through vias 272, and internal connection structure 112 that are electrically connected may be referred to as a power transmission line. In exemplary implementations, the power transmission line may be configured for the package substrate 100 to provide power received from a device outside the semiconductor package SP4 to at least one of the logic die LD and the plurality of memory core dies 310.

This disclosure may provide a semiconductor package SP4 with improved integration.

According to the present disclosure, a semiconductor package with improved integration may be provided.

While the present disclosure has been described with reference to implementations thereof, it will be apparent to those of ordinary skill in the art that various changes and modifications may be made thereto without departing from the spirit and scope of the present disclosure as set forth in the following claims.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a plurality of stacked memory core dies connected to first data lines;
a logic die comprising a processor connected to second data lines; and
a buffer die stacked between the plurality of stacked memory core dies and the logic die, the buffer die comprising a data line reconfiguration circuit connected to the first data lines and the second data lines,
wherein the data line reconfiguration circuit comprises at least one of a multiplexer circuit, a serializer/deserializer circuit, or a compressor.

2. The semiconductor package of claim 1, wherein a total number of the first data lines is greater than a total number of the second data lines.

3. The semiconductor package of claim 2, wherein the buffer die comprises:
a plurality of first bonding pads formed on an upper part of the buffer die and connected to the first data lines; and
second connection bonding pads formed on a lower part of the buffer die and connected to the second data lines.

4. The semiconductor package of claim 3, wherein the buffer die comprises:
a first silicon substrate layer; and
first connection through vias that extend through the first silicon substrate layer and are connected to the data line reconfiguration circuit and the plurality of first bonding pads.

5. The semiconductor package of claim 4, wherein the logic die comprises:
first connection bonding pads formed on an upper part of the logic die and connected to the second data lines;
a second silicon substrate layer; and
second connection through vias that extend through the second silicon substrate layer and are connected to the second data lines and the first connection bonding pads.

6. The semiconductor package of claim 5, wherein the first connection bonding pads and the second connection bonding pads are connected by metal-metal hybrid bonding.

7. The semiconductor package of claim 1, wherein the logic die comprises a direct access interface configured to test the plurality of stacked memory core dies.

8. The semiconductor package of claim 1, wherein a number of the first data lines is between 512 and 2048.

9. The semiconductor package of claim 8, comprising:
a plurality of second bonding pads between the plurality of stacked memory core dies and the buffer die and connected to the plurality of stacked memory core dies,
wherein the buffer die comprises a plurality of first bonding pads formed on an upper part of the buffer die and connected to the first data lines, and
wherein the plurality of first bonding pads and the plurality of second bonding pads are connected by metal-metal hybrid bonding.

10. The semiconductor package of claim 1, comprising:
a first lower power through via that extends through the logic die;
a first upper power through via that extends through the buffer die; and
a plurality of second power through vias that extend through the plurality of stacked memory core dies,
wherein the first lower power through via, the first upper power through via, and the plurality of second power through vias are electrically connected to each other and configured to supply power to at least one of the plurality of stacked memory core dies, the buffer die, and the logic die.

11. A semiconductor package comprising:
a logic die; and
a plurality of memory core dies stacked on the logic die,
wherein the logic die comprises
a processor;
a data line reconfiguration circuit;
first data lines connected to the plurality of memory core dies and the data line reconfiguration circuit; and
second data lines connected to the processor and the data line reconfiguration circuit,
wherein the data line reconfiguration circuit comprises at least one of a multiplexer circuit, a serializer/deserializer circuit, or a compressor.

12. The semiconductor package of claim 11, wherein a total number of the first data lines is greater than a total number of the second data lines.

13. The semiconductor package of claim 11, wherein the logic die comprises:
a plurality of first connection bonding pads formed on an upper part of the logic die and connected to the plurality of memory core dies;
a silicon substrate layer;
connection through vias that extend through the silicon substrate layer and are connected to the first data lines and the plurality of first connection bonding pads.

14. The semiconductor package of claim 13, comprising:
a plurality of second bonding pads between the plurality of memory core dies and the logic die and connected to the plurality of memory core dies,
wherein the plurality of first connection bonding pads and the plurality of second bonding pads are connected by metal-metal hybrid bonding.

15. The semiconductor package of claim 11, wherein the logic die comprises:
a direct access interface configured to test the plurality of memory core dies; and
third data lines connected to the direct access interface and the data line reconfiguration circuit.

16. The semiconductor package of claim 11, wherein a total number of the first data lines is between 512 and 2048.

17. The semiconductor package of claim 11, comprising:
a first power through via that extends through the logic die;
a plurality of second power through vias that extend through the plurality of memory core dies,
wherein the first power through via and the plurality of second power through vias are electrically connected to each other and are configured to supply power to at least one of the memory core dies and the logic die.

18. A semiconductor package comprising:
a package substrate;
a logic die stacked on the package substrate, the logic die comprising a processor;
a buffer die stacked on the logic die; and
a memory core die stacked on the buffer die,
wherein the buffer die comprises
a data line reconfiguration circuit;
a plurality of first bonding pads configured to electrically connect the data line reconfiguration circuit and the memory core die; and
a plurality of second connection bonding pads configured to electrically connect the data line reconfiguration circuit and the processor,
wherein a total number of the plurality of first bonding pads is greater than a total number of the plurality of second connection bonding pads, and
wherein the data line reconfiguration circuit comprises at least one of a multiplexer circuit, a serializer/deserializer circuit, or a compressor.

19. The semiconductor package of claim 18, wherein the logic die comprises:
first connection bonding pads on an upper part of the logic die and configured to be electrically connected to the processor;
a first silicon substrate layer; and
first connection through vias that extend through the first silicon substrate layer and connect with the first connection bonding pads.

20. The semiconductor package of claim 19, wherein the buffer die comprises:
a second silicon substrate layer between the data line reconfiguration circuit and the plurality of second connection bonding pads; and
second connection through vias that extend through the second silicon substrate layer and connect with the data line reconfiguration circuit and the plurality of second connection bonding pads.
